(19) United States
(12) Patent Application Publication
(10) Pub. No.: US 2025/0366109 A1
(43) Pub. Date: Nov. 27, 2025

(54) EPITAXIAL STRUCTURES IN SEMICONDUCTOR DEVICES

(71) Applicant: Taiwan Semiconductor Manufacturing Company, Ltd., Hsinchu (TW)

(72) Inventors: Chien-Wei LEE, Kaohsiung City (TW); Chien-I KUO, Zhubei (TW); Ming-Hua YU, Hsinchu City (TW)

(73) Assignee: Taiwan Semiconductor Manufacturing Company, Ltd., Hsinchu (TW)

(21) Appl. No.: 19/292,768

(22) Filed: Aug. 6, 2025

Related U.S. Application Data
(63) Continuation of application No. 18/404,233, filed on Jan. 4, 2024.
(60) Provisional application No. 63/536,771, filed on Sep. 6, 2023.

(51) Int. Cl. H10D 62/13; H10D 30/01; H10D 30/43; H10D 30/67; H10D 62/10; H10D 64/01; H10D 64/23; H10D 84/83

(52) U.S. Cl. CPC H10D 62/151; H10D 30/014; H10D 30/43; H10D 30/6735; H10D 30/6757; H10D 62/121; H10D 64/018; H10D 64/258; H10D 84/83

(57) ABSTRACT

A semiconductor device and a method of fabricating the semiconductor device are disclosed. The semiconductor device includes a substrate, first and second nanostructured channel regions disposed on the substrate, a gate structure surrounding the first and second nanostructured channel regions, an inner gate spacer disposed along a sidewall of the gate structure and between the first and second nanostructured channel regions, and a source/drain (S/D) region. The S/D region includes an epitaxial liner disposed along sidewalls of the first and second nanostructured channel regions and the inner gate spacer and a germanium-based epitaxial region disposed on the epitaxial liner. The semiconductor further includes an isolation structure disposed between the germanium-based epitaxial region and the substrate.

### CROSS-REFERENCE TO RELATED APPLICATIONS

This application is a continuation of U.S. patent application Ser. No. 18/404,233, titled “Epitaxial Structures in Semiconductor Devices,” filed Jan. 4, 2024, which claims the benefit of U.S. Provisional Patent Application No. 63/536,771, titled “Nanosheet P-type Doped Si Layer,” filed Sep. 6, 2023, each of which is incorporated by reference herein in its entirety.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs and fin field effect transistors (finFETs). Such scaling down has increased the complexity of semiconductor manufacturing processes.

### BRIEF DESCRIPTION OF THE DRAWINGS

Aspects of this disclosure are best understood from the following detailed description when read with the accompanying figures.

FIGS. 1A and 1G illustrate different isometric views of a semiconductor device with epitaxial liners in a source/drain (S/D) region, in accordance with some embodiments.

FIGS. 1B-1E and 1H-1O illustrate different cross-sectional views of a semiconductor device with epitaxial liners in a S/D region, in accordance with some embodiments.

FIG. 1F illustrates a top-down view of a semiconductor device with an epitaxial liner, in accordance with some embodiments.

FIG. 2 is a flow diagram of a method for fabricating a semiconductor device with epitaxial liners in a S/D region, in accordance with some embodiments.

FIGS. 3-9 illustrate cross-sectional views of a semiconductor device with epitaxial liners in a S/D region at various stages of its fabrication process, in accordance with some embodiments.

FIGS. 10A-13B illustrate cross-sectional views of a semiconductor device with n- and p-type FETs at various stages of its fabrication process, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Spatially relative terms, such as “beneath,” “below,” “lower,” “above,” “upper,” and the like may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5-20% of the value (e.g., ±1%, ±2%, ±3%, ±4%, ±5%, ±10%, ±10-15%, ±15-20% of the value). These values are merely examples and are not intended to be limiting. The terms “about” and “substantially” can refer to a percentage of the values as interpreted by those skilled in relevant art(s) in light of the teachings herein.

The gate-all-around (GAA) transistor structures may be patterned by any suitable method. For example, the structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA transistor structure.

GAA FETs can include fin bases (also referred to as “sheet bases”) disposed on a substrate, stacks of nanostructured channel regions disposed on the fin bases, gate structures surrounding each of the nanostructured channel regions, and inner spacers on sidewalls of the gate structures. The GAA FETs can further include S/D regions, each of which can be disposed between a pair of nanostructured channel regions and on a fin portion between the pair of nanostructured channel regions. Each of the S/D regions can be formed by the merging of an epitaxial portion grown on the fin portion with epitaxial portions grown on sidewalls of the pair of nanostructured channel regions. The direction and/or location of the merging of the epitaxial portions can be challenging to control, which can lead to the formation of voids in the S/D regions. Also, due to the growth of the epitaxial portions on different surfaces, any lattice mismatch between the epitaxial portions can induce crystal defects, such as dislocations in the S/D regions. The presence of such voids and/or crystal defects in the S/D regions can degrade the performance of the GAA FETs. Furthermore, the merged portions of the p-type S/D regions—having a high concentration of germanium (Ge) atoms—can be in contact with the inner spacers, which can lead to high parasitic resistances and capacitances and high drain-induced barrier lowering (DIBL) effects in the GAA FETs, thus degrading device performance.

To address the abovementioned challenges of forming epitaxial S/D regions in GAA FETs, the present disclosure provides example methods of forming epitaxial p-type S/D regions on nanostructured channel regions to improve the epitaxial growth quality of the p-type S/D regions and reduce parasitic resistances and capacitances and DIBL effects in the GAA FETs. In some embodiments, a p-type S/D region can include a Ge-based epitaxial region and epitaxial liners along sidewalls of the Ge-based epitaxial region. The epitaxial liners can be formed as a continuous layer on sidewalls of the nanostructured channel regions and inner spacers facing the Ge-based epitaxial region of the p-type S/D region. And, the Ge-based epitaxial region can be epitaxially grown on the epitaxial liners. The epitaxial growth of the Ge-based epitaxial region on the continuous layer of the epitaxial liners can improve the epitaxial growth quality of the Ge-based epitaxial region by preventing or minimizing the formation of defects in the Ge-based epitaxial region, thus improving the S/D performance. The epitaxial liners can also prevent the Ge-based epitaxial region from being in contact with the inner spacers, thus reducing parasitic resistances and capacitances and DIBL effects in the GAA FETs.

In some embodiments, the Ge-based epitaxial region can include a silicon-germanium (SiGe) region with a Ge concentration of about 15 atomic % to about 50 atomic %. In some embodiments, the epitaxial liners can include an undoped silicon (Si) layer or a doped Si layer. In some embodiments, the doped Si layer can include boron and/or gallium dopants. In some embodiments, the concentration of boron and/or gallium dopants can be about 1×10²⁰ atoms/cm³ to about 5×10²¹ atoms/cm³. In some embodiments, the epitaxial liners can be Ge-free or can have a low concentration of Ge atoms (e.g., about 1 atomic % to about 20 atomic %, or about 6 atomic % to about 12 atomic %). In some embodiments, the portions of the epitaxial liners on the sidewalls of the nanostructured channel regions can be thicker than the portions of the epitaxial liners on the sidewalls of the inner spacers. In some embodiments, the epitaxial liners can have a thickness of about 1 nm to about 12 nm for adequately forming a continuous layer on the sidewalls of the nanostructured channel regions and inner spacers facing the Ge-based epitaxial region.

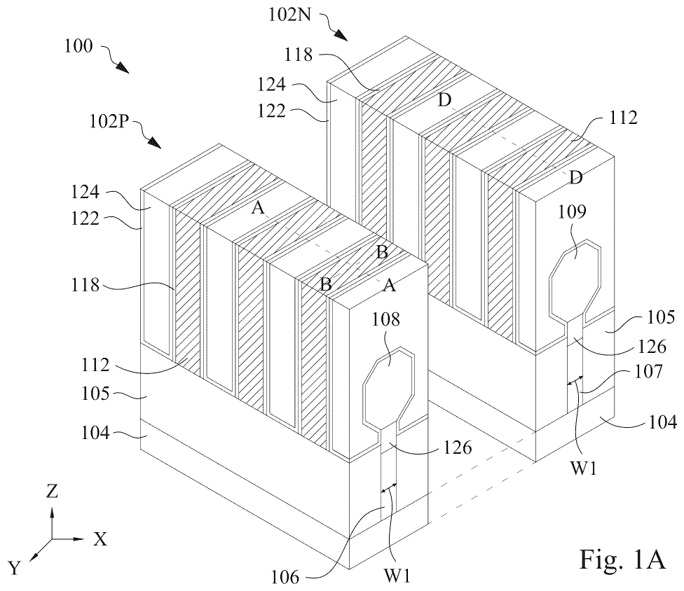

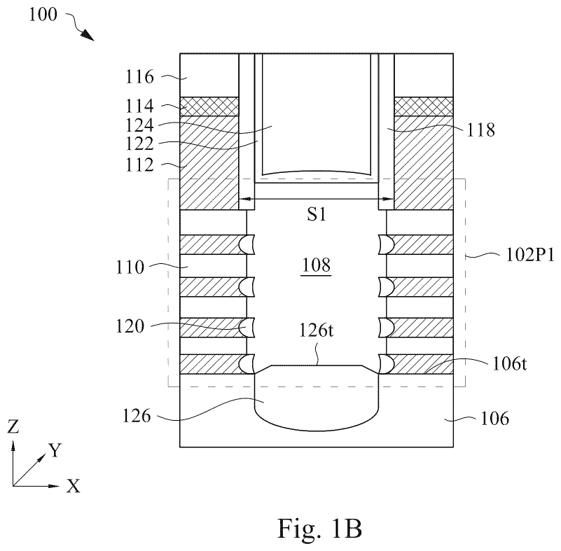

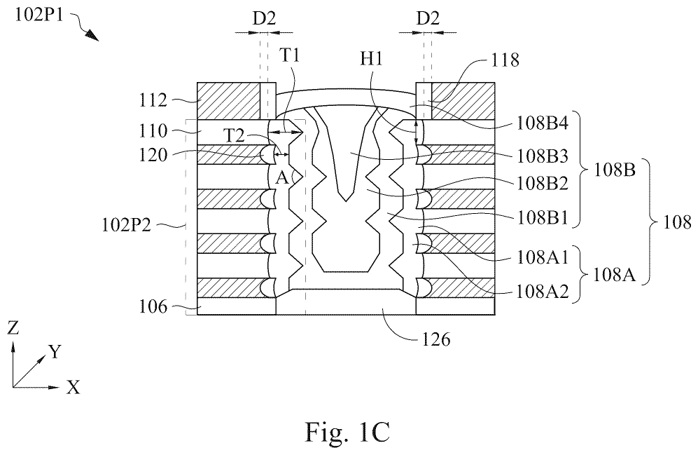

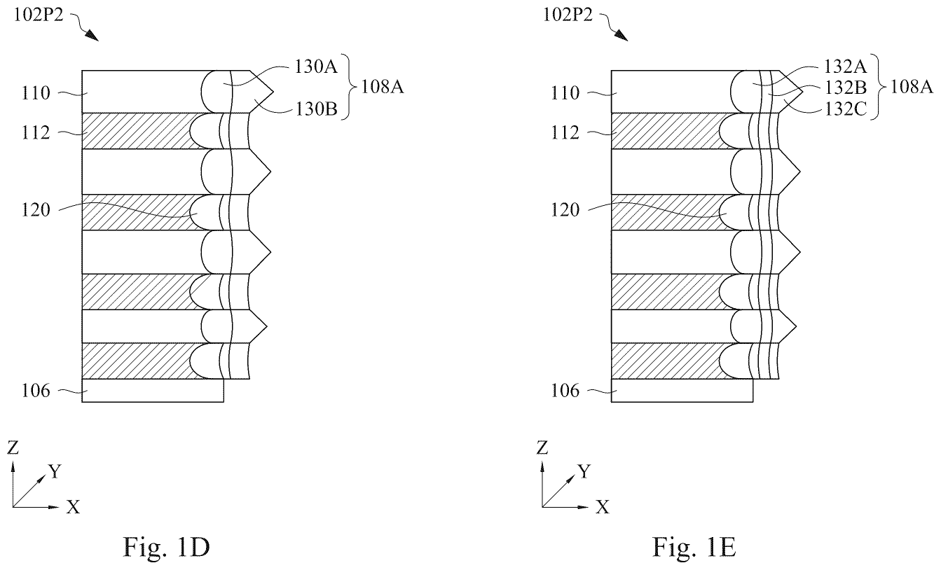

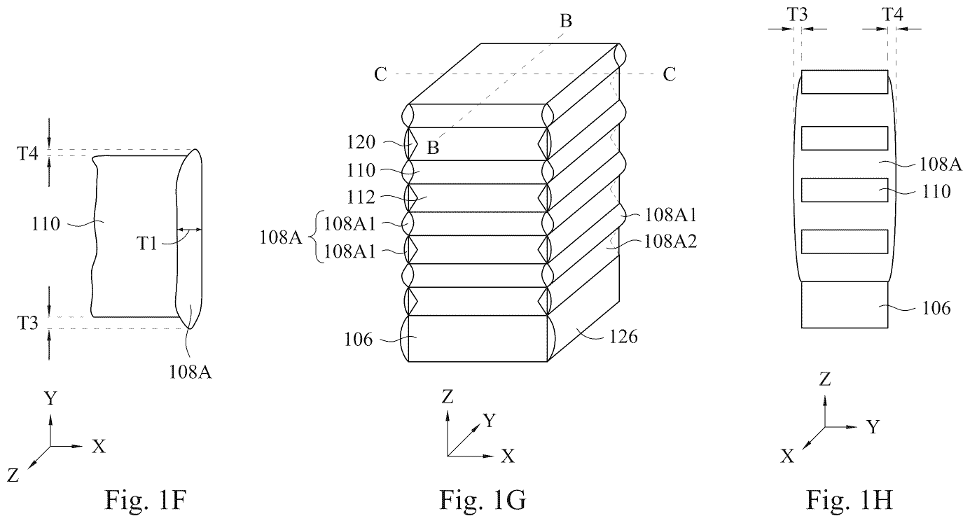

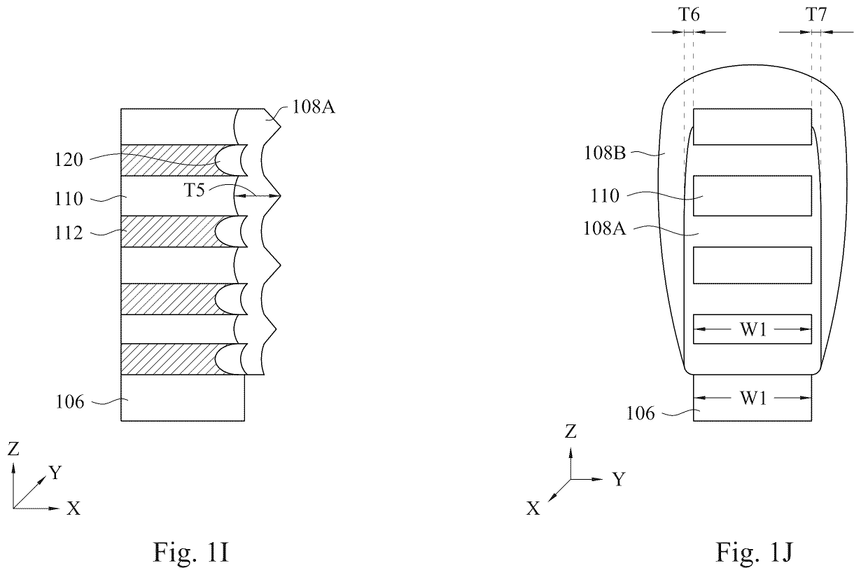

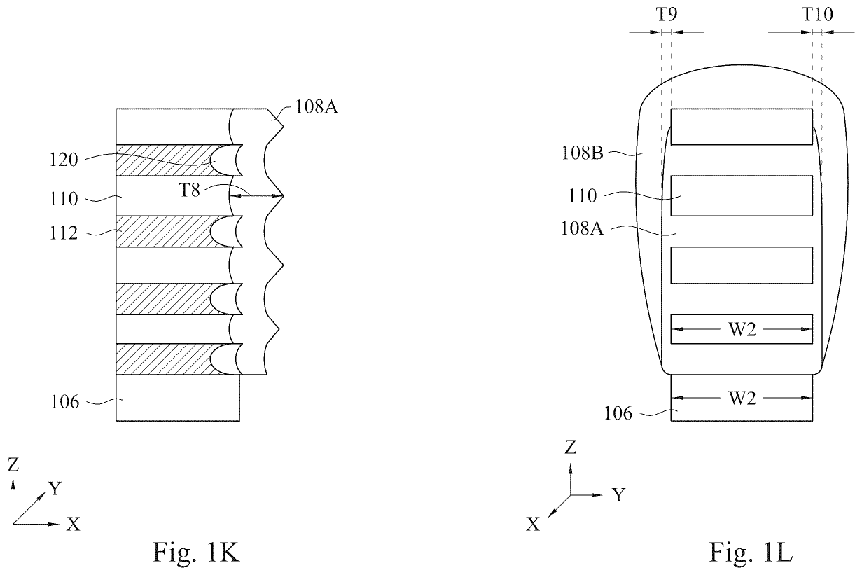

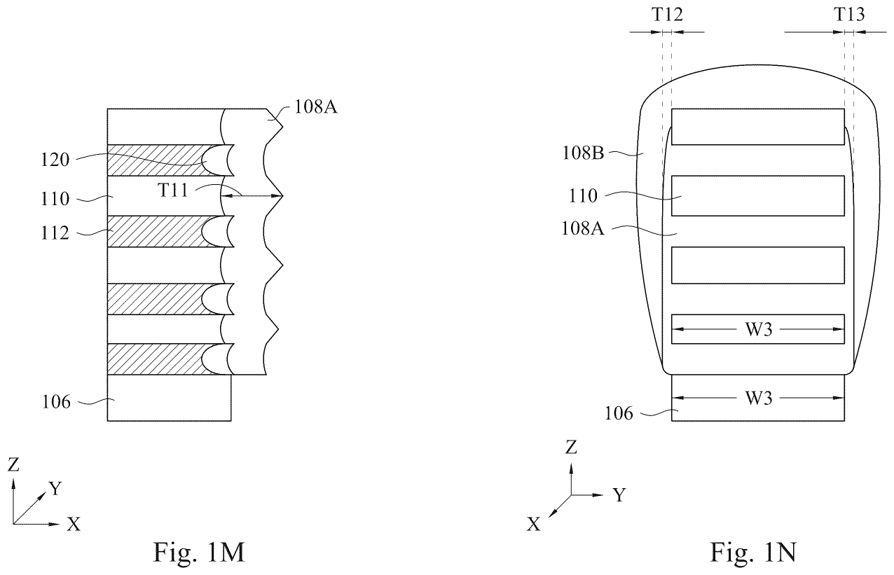

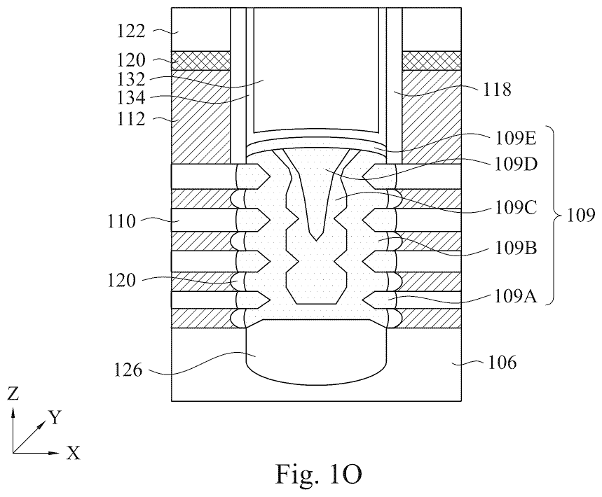

FIG. 1A illustrates an isometric view of a semiconductor device 100 with a PFET 102P and an NFET 102N (also referred to as “GAA PFET 102P and GAA NFET 102N”), according to some embodiments. FIG. 1B illustrates a cross-sectional view of PFET 102P along line A-A of FIG. 1A with additional structures that are not shown in FIG. 1A for simplicity, according to some embodiments. FIG. 1C illustrates an enlarged cross-sectional view of a region 102P1 of FIG. 1B with additional structures that are not shown in FIG. 1B for simplicity, according to some embodiments. FIGS. 1D and 1E illustrate different enlarged cross-sectional views of a region 102P2 of FIG. 1C with additional structures that are not shown in FIG. 1C for simplicity, according to some embodiments. FIG. 1F illustrates a top-down view of region 102P2 of FIG. 1C, according to some embodiments. FIG. 1G illustrates an isometric view of region 102P2 of FIG. 1C, according to some embodiments. FIGS. 1H, 1J, IL, and IN illustrate different cross-sectional views along line B-B of FIGS. 1A and 1G, according to some embodiments. FIGS. 1I, 1K, and 1M illustrate different cross-sectional views along line C-C of FIG. 1G, according to some embodiments. FIG. 1O illustrates a cross-sectional view of NFET 102N along line D-D of FIG. 1A with additional structures that are not shown in FIG. 1A for simplicity, according to some embodiments. The discussion of elements in FIGS. 1A-1O with the same annotations applies to each other, unless mentioned otherwise.

Semiconductor device 100 can be formed on a substrate 104 with PFET 102P and NFET 102N formed on different regions of substrate 104. There may be other FETs and/or structures (e.g., isolation structures) formed between PFET 102P and NFET 102N on substrate 104. In some embodiments, substrate 104 can be a semiconductor material, such as Si, Ge, SiGe, a silicon-on-insulator (SOI) structure, and a combination thereof. Further, substrate 104 can be doped with p-type dopants (e.g., boron, indium, aluminum, or gallium) or n-type dopants (e.g., phosphorus or arsenic). Semiconductor device 100 can further include shallow trench isolation (STI) regions 105 disposed on substrate 104. STI regions 105 can include an insulating material, such as silicon oxide (SiO₂), silicon nitride (SiN), silicon oxynitride (SiON), silicon oxycarbide (SiOC), silicon carbon nitride (SiCN), silicon oxycarbon nitride (SiOCN), and silicon germanium oxide (SiGeOₓ).

Referring to FIGS. 1A and 1B, in some embodiments, PFET 102P can include a fin base 106 (also referred to as a “sheet base 106”) disposed on substrate 104, (ii) S/D regions 108 disposed on fin base 106, (iii) nanostructured channel regions 110 disposed adjacent to S/D regions 108, (iv) gate structures 112 surrounding nanostructured channel regions 110, (v) conductive capping layers 114, (vi) insulating capping layers 116, (vii) outer gate spacers 118 disposed along sidewalls of gate structures 112, (viii) inner gate spacers 120 disposed along sidewalls of S/D regions 108, (ix) ESLs 122 disposed directly on S/D regions 108, (x) ILD layers 124 disposed directly on ESLs 122, and (xi) isolation structures 126. S/D regions 408 may refer to a source or a drain, individually or collectively dependent upon the context.

In some embodiments, fin base 106 can include a material similar to substrate 104. Fin base 106 can have elongated sides extending along an X-axis. In some embodiments, nanostructured channel regions 110 can be in the form of nanosheets, nanowires, nanorods, nanotubes, or other suitable nanostructured shapes. As used herein, the term “nanostructured” defines a structure, layer, and/or region as having a horizontal dimension (e.g., along an X- and/or Y-axis) and/or a vertical dimension (e.g., along a Z-axis) less than about 100 nm, for example about 90 nm, about 50 nm, about 10 nm, or other values less than about 100 nm. Nanostructured channel regions 110 can include semiconductor materials similar to or different from substrate 104. In some embodiments, nanostructured channel regions 110 can include Si, silicon arsenide (SiAs), silicon phosphide (SiP), silicon carbide (SiC), silicon carbon phosphide (SiCP), silicon germanium (SiGe), silicon germanium boron (SiGeB), germanium boron (GeB), silicon germanium stannum boron (SiGeSnB), a III-V semiconductor compound, or other suitable semiconductor materials. In some embodiments, each of nanostructured channel regions 110 can have a thickness of about 3 nm to about 15 nm along a Z-axis. Though rectangular cross-sections of nanostructured channel regions 110 are shown, nanostructured channel regions 110 can have cross-sections of other geometric shapes (e.g., circular, elliptical, triangular, or polygonal).

Each gate structure 112 can be a multi-layered structure and can surround nanostructured channel regions 110 for which gate structures 112 an be referred to as “GAA structures” and PFET 102P can be referred to as GAA FET 102P. In some embodiments, a gate spacing SI can be about 15 nm to about 25 nm. The gate spacing SI is defined as a distance along an X-axis between adjacent gate structures 112. In some embodiments, each gate structure 112 can include (i) an interfacial oxide (IL) layer, (ii) a high-k (HK) gate dielectric layer disposed on the IL layer, (iii) a work function metal (WFM) layer disposed on the HK gate dielectric layer, and (iv) a gate metal fill layer disposed on the WFM layer. The different layers of gate structures 112 are not shown for simplicity.

In some embodiments, the IL layer can include SiO₂, silicon germanium oxide (SiGeOₓ), or germanium oxide (GeOₓ). In some embodiments, the HK gate dielectric layer can include a HK dielectric material, such as hafnium oxide (HfO₂), titanium oxide (TiO₂), hafnium zirconium oxide (HfZrO), tantalum oxide (Ta₂O₃), hafnium silicate (HfSiO₄), zirconium oxide (ZrO₂), zirconium aluminum oxide (ZrAlO), zirconium silicate (ZrSiO₂), lanthanum oxide (La₂O₃), aluminum oxide (Al₂O₃) zinc oxide (ZnO), hafnium zinc oxide (HfZnO), and yttrium oxide (Y₂O₃). In some embodiments, the WFM layer can include substantially Al-free (e.g., with no Al) titanium (Ti)-based or tantalum (Ta)-based nitrides or alloys, such as titanium nitride (TiN), titanium silicon nitride (TiSiN), titanium gold (Ti—Au) alloy, titanium copper (Ti—Cu) alloy, tantalum nitride (TaN), tantalum silicon nitride (TaSiN), tantalum gold (Ta—Au) alloy, and tantalum copper (Ta—Cu). In some embodiments, the gate metal fill layer can include a suitable conductive material, such as tungsten (W), titanium (Ti), silver (Ag), ruthenium (Ru), molybdenum (Mo), copper (Cu), cobalt (Co), Al, iridium (Ir), nickel (Ni), metal alloys, and a combination thereof.

Conductive capping layers 114 can provide conductive interfaces between gate structures 112 and gate contact structures (not shown) to electrically connect gate structures 112 to the gate contact structures without forming the gate contact structures directly on or within gate structures 112. The gate contact structure is not formed directly on or within gate structures 112 to prevent contamination of gate structures 112 by any of the processing materials used in the formation of the gate contact structures. In some embodiments, conductive capping layers 114 can include a metallic material, such as W, Ru, Mo, Co, other suitable metallic materials, and a combination thereof.

Insulating capping layers 116 can be disposed directly on conductive capping layers 114 and can protect the underlying conductive capping layers 114 from structural and/or compositional degradation during subsequent processing of semiconductor device 100. In some embodiments, insulating capping layers 116 can include a dielectric nitride or carbide material, such as silicon nitride (SiN), silicon oxynitride (SiON), silicon carbon nitride (SiCN), silicon carbide (SiC), silicon carbon oxynitride (SiCON), and other suitable dielectric nitride or carbide materials.

In some embodiments, gate structures 112 can be electrically isolated from adjacent S/D regions 108 by outer gate spacers 118. In some embodiments, outer gate spacers 118 can include an insulating material, such as SiO₂, SiN, SiCN, SiOCN, and a combination thereof. In some embodiments, the portions of gate structures 112 surrounding nanostructured channel regions 110 can be electrically isolated from adjacent S/D regions 108 by inner gate spacers 120. Inner gate spacers 120 can include an insulating material, such as SiOₓ, SiN, SiCN, SiOCN, and a combination thereof.

In some embodiments, ESLs 122 can have a dielectric constant of about 4 to about 7. In some embodiments, ESLs 122 can include a dielectric material, such as lanthanum oxide (LaO), aluminum oxide (Al₂O₃), yttrium oxide (Y₂O₃), tantalum carbon nitride (TaCN), zirconium silicide (ZrSi), SiOCN, SiOC, SiCN, zirconium nitride (ZrN), zirconium aluminum oxide (ZrAIO), TiO₂, Ta₂O₃, ZrO₂, HfO₂, SiN, hafnium silicide (HfSi), aluminum oxynitride (AlON), SiO₂, SiC, SiN, and zinc oxide (ZnO). In some embodiments, ILD layers 124 can be disposed directly on ESLs 122. In some embodiments, ILD layers 124 can include an insulating material, such as SiO₂, SiN, SION, SiCN, and SiOCN. In some embodiments, top surfaces of ILD layer 124, ESLs 122, and insulating capping layers 116 can be substantially coplanar with each other.

In some embodiments, isolation structures 126 can be disposed under S/D regions 108 and in recessed regions of fin base 106. The recessed region in fin base 106 can be formed during the formation of S/D regions 108, as described in detail below. Isolation structures 126 can prevent the epitaxial growth of S/D regions 108 on fin base 106 and prevent the diffusion of dopants from S/D region 108 to fin base 106, thus preventing current leakage between S/D regions 108 and short channel effects in PFET 102P. In some embodiments, each isolation structure 110 can include an undoped Si layer.

In some embodiments, top surfaces 126t of isolation structures 110 can be higher than top surface 106t of fin base 106. In some embodiments, isolation structures 110 can extend a distance D1 of about 10 nm to about 20 nm into fin base 106. In some embodiments, if distance D1 is below about 10 nm, isolation structures 110 may not adequately prevent the diffusion of dopants from S/D regions 108 to fin base 106. On the other hand, if distance D1 is above about 20 nm, the processing time (e.g., etching time, deposition time) for forming isolation structures 110 increases, and consequently increases the manufacturing cost of PFET 102P.

Referring to FIGS. 1A-1C, in some embodiments, each S/D region 108 can be disposed above fin base 106 and can be electrically isolated from fin base 106 by isolation structure 126. In some embodiments, each S/D region 108 can include (i) a pair of epitaxial liners 108A facing each other and (ii) a Ge-based epitaxial region 108B. Each epitaxial liner 108A can form a continuous layer on sidewalls of nanostructured channel regions 110 and inner gate spacers 120 that are facing S/D region 108 and are along a YZ-plane. The continuous layers of epitaxial liners 108A can act as seeding layers for the epitaxial grown of Ge-based epitaxial region 108B. The epitaxial growth of Ge-based epitaxial region 108B on the continuous layers of epitaxial liners 108A can improve the epitaxial growth quality of Ge-based epitaxial region 108B by preventing or minimizing the formation of defects in Ge-based epitaxial region 108B, thus improving the performance of PEFT 102B. Epitaxial liners 108A can also prevent the Ge-based epitaxial region 108B from being in contact with inner gate spacers 120, thus reducing parasitic resistances and capacitances and DIBL effects in PFET 102P. Furthermore, epitaxial liners 108A can act as an ESL and protect Ge-based epitaxial region from being etched during the formation of gate structures 112, as described in detail below.

First portions 108A1 of epitaxial liner 108A can be disposed directly on and can be epitaxially grown on the sidewalls of nanostructured channel regions 110 that are facing S/D region 108 and are along a YZ-plane. Second portions 108A2 of epitaxial liner 108A can be disposed directly on the sidewalls of inner gate spacers 126 that are facing S/D region 108 and are along a YZ-plane. Second portions 108A2 of epitaxial liner 108A can be formed by the merging of adjacent first portions 108A1 of epitaxial liner 108A. In some embodiments, a sidewall of epitaxial liner 108A in contact with the sidewalls of nanostructured channel regions 110 and inner gate spacers 120 can have a curved cross-sectional profile. In some embodiments, sidewalls of first portions 108A1 in contact with Ge-based epitaxial region 108B can have faceted cross-sectional profiles and sidewalls of second portions 108A2 in contact with Ge-based epitaxial region 108B can have curved cross-sectional profiles. In some embodiments, the faceted cross-sectional profile can have faceted angles A of about 60 degrees to about 180 degrees. In some embodiments, the crystal orientation of the faceted sidewalls of first portions 108A1 along an X-axis can be the same as the crystal orientation of substrate 104.

In some embodiments, epitaxial liner 108A can be an undoped Si layer or a doped Si layer. In some embodiments, epitaxial liner 108A can include a Si layer with a boron dopant concentration of about 1×10²⁰ atoms/cm³ to about 5×10²¹ atoms/cm³ or about 6×10²⁰ atoms/cm³ to about 8×10²⁰ atoms/cm³. In some embodiments, epitaxial liner 108A can include a Si layer with a gallium dopant concentration of about 1×10²⁰ atoms/cm³ to about 5×10²¹ atoms/cm³. In some embodiments, epitaxial liner 108A can be Ge-free or can include a low Ge concentration of about 1 atomic % to about 20 atomic % or about 6 atomic % to about 12 atomic %.

In some embodiments, epitaxial liner 108A can include a stack of two layers-outer liner 130A and inner liner 130B, as shown in FIG. 1D. Outer liner 130A can form a continuous layer on sidewalls of nanostructured channel regions 110 and inner gate spacers 120 that are facing S/D region 108 and are along a YZ-plane. Inner liner 130B can be disposed on and can form a continuous layer on outer liner 130A. In some embodiments, outer liner 130A can include an undoped Si layer and inner liner 130B can include a doped Si layer with a boron dopant concentration of about 1×10²⁰ atoms/cm³ to about 5×10²¹ atoms/cm³ or about 6×10²⁰ atoms/cm³ to about 8×10²⁰ atoms/cm³ or a gallium dopant concentration of about 1×10²⁰ atoms/cm³ to about 5×10²¹ atoms/cm³. In some embodiments, outer liner 130A and inner liner 130B can be Ge-free or can include a low Ge concentration of about 1 atomic % to about 20 atomic % or about 6 atomic % to about 12 atomic %. In some embodiments, inner liner 130B can be thicker along an X-axis than outer liner 130A.

In some embodiments, epitaxial liner 108A can include a stack of three layers-outer liner 132A, middle liner 132B, and inner liner 132C, as shown in FIG. 1E. Outer liner 132A can form a continuous layer on sidewalls of nanostructured channel regions 110 and inner gate spacers 120 that are facing S/D region 108 and are along a YZ-plane. Middle liner 132B can be disposed on and can form a continuous layer on outer liner 132A. Inner liner 132C can be disposed on and can form a continuous layer on middle liner 132B. In some embodiments, middle liner 132B can include an undoped Si layer and outer and inner liners 132A and 132C can include a doped Si layer. In some embodiments, outer liner 132A can have a dopant concentration lower than a dopant concentration of inner liner 132C. In some embodiments, outer liner 132A can have a boron or gallium dopant concentration of about 1×10²⁰ atoms/cm³ to about 3×10²⁰ atoms/cm³ and inner liner 132C can have a boron or gallium dopant concentration of about 8×10²⁰ atoms/cm³ to about 1×10²¹ atoms/cm³. In some embodiments, outer liner 132A, middle liner 132B, and inner liner 132C can be Ge-free or can include a low Ge concentration of about 1 atomic % to about 20 atomic % or about 6 atomic % to about 12 atomic %. In some embodiments, inner liner 132C can be thicker along an X-axis than middle liner 132B and outer liner 132A.

Referring to FIG. 1C, in some embodiments, first portions 108A1 of epitaxial liner 108A can have a thickness T1 of about 1 nm to about 12 nm or about 1.3 nm to about 2.3 nm. In some embodiments, second portions 108A2 of epitaxial liner 108A can have a thickness T2 of about 1 nm to about 12 nm or about 0.5 nm to about 1.5 nm. In some embodiments, thickness T1 can be greater than thickness T2. In some embodiments, first portions 108A1 of epitaxial liner 108A with boron and germanium dopants can have a smaller aspect ratio (ratio between thickness T1 and height H1) than Ge-free first portions 108A1 of epitaxial liner 108A with boron dopants. In some embodiments, first portions 108A1 with boron dopants and about 6 atomic % of Ge can have an aspect ratio (T1:H1) of about 1:3 to about 1:4 and Ge-free first portions 108A1 with boron dopants can have an aspect ratio (T1:H1) of about 1:2. In some embodiments, first portions 108A1 of epitaxial liner 108A can have an aspect ratio (T1:H1) of about 1:4 to about 1:6 when formed on a stack of two to five nanostructured channel regions 110. In some embodiments, when epitaxial liner 108A is formed on a stack of more than five nanostructured channel regions 110, the aspect ratio of first portion 108A1 formed on the topmost nanostructured channel region 110 can be greater than the aspect ratio of first portion 108A1 formed on the bottommost nanostructured channel region 110.

In some embodiments, first portions 108A1 of epitaxial liner 108A can extend below outer gate spacers 118 to be within a distance D2 of about 1 nm to about 2 nm away from adjacent gate structure 112. Within this range of distance D2, epitaxial liners 108A can reduce or minimize the channel resistance in nanostructured channel regions 110. Epitaxial liners 108A having the above discussed concentrations and/or dimensions can adequately function as an ESL and reduce or minimize parasitic resistances and capacitances and DIBL effects in PFET 102P.

FIGS. 1F and 1G illustrate a top-down view and an isometric view, respectively, of region 102P2 of FIG. 1C, and FIG. 1H illustrates a cross-sectional view along line B-B of FIG. 1G. Gate structures 112 surrounding nanostructured channel regions 110 and inner gate spacers 120 are not shown in FIG. 1H for simplicity. In some embodiments, epitaxial liner 108A can be wider than nanostructured channel regions 110 along a Y-axis, as shown in FIGS. 1F, 1G, and 1H. Epitaxial liner 108A can laterally extend by thicknesses T3 and T4 on either sides of nanostructured channel regions 110, as shown in FIGS. 1F and 1H. In some embodiments, thicknesses T3 and T4 can be about 1 nm to about 12 nm.

In some embodiments, the thickness of epitaxial liner 108A along an X-axis and the width of epitaxial liner 108A along a Y-axis can be varied with variations in the widths of nanostructured channel regions 110 and fin base 106, as illustrated with FIGS. 1I-IN. FIGS. 1I, 1K, and 1M illustrate different cross-sectional views along line C-C of FIG. 1G for different widths of nanostructured channel regions 110 and fin base 106. FIGS. 1J, IL, and IN illustrate different cross-sectional views along line B-B of FIG. 1G for different widths of nanostructured channel regions 110 and fin base 106. In some embodiments, the thickness of epitaxial liner 108A along an X-axis can be increased from thickness T5 (FIG. 1I) to thickness T8 (FIG. 1K) and to thickness T11 (Fig. M) when the widths of nanostructured channel regions 110 and fin base 106 are increased from width W1 (FIG. 1J) to width W2 (FIG. 1L) and to width W3 (Fig. N). In some embodiments, thickness T5 can be about 1 nm to about 10 nm when width W1 is about 11 nm, thickness T8 can be about 1.5 nm to about 15 nm when width W2 is about 20 nm, and thickness T11 can be about 2 nm to about 20 nm when width W3 is about 100 nm.

Similarly, in some embodiments, the widths of epitaxial liner 108A and Ge-based epitaxial region 108B along a Y-axis can be increased when the widths of nanostructured channel regions 110 and fin base 106 are increased from width W1 (FIG. 1J) to width W2 (FIG. 1L) and to width W3 (Fig. N). As a result, the thicknesses of the extended portions of epitaxial liner 108A that extend over the sides of nanostructured channel regions 110 increases along a Y-axis, as shown in FIGS. 1J, IL, and IN. In some embodiments, the extended portions of epitaxial liner 108A can have thicknesses T6 and T7 of about 1 nm to about 3 nm when width W1 is about 11 nm, as shown in FIG. 1J. In some embodiments, the extended portions of epitaxial liner 108A can have thicknesses T9 and T10 of about 1.5 nm to about 5 nm when width W2 is about 20 nm, as shown in FIG. 1L. In some embodiments, the extended portions of epitaxial liner 108A can have thicknesses T12 and T13 of about 2 nm to about 10 nm when width W3 is about 100 nm, as shown in FIG. 1N.

Referring to FIG. 1C, Ge-based epitaxial region 108B can be disposed on and in contact with epitaxial liners 108A and isolation structure 126. In some embodiments, Ge-based epitaxial region 108B can include (i) an epitaxial sub-region 108B1 epitaxially grown on epitaxial liners 108A and isolation structure 126, (ii) an epitaxial sub-region 108B2 epitaxially grown on epitaxial sub-region 108B1, (iii) an epitaxial sub-region 108B3 epitaxially grown on epitaxial sub-region 108B2, and (iv) an epitaxial sub-region 108B4 epitaxially grown on epitaxial sub-regions 108B1, 108B2, and 108B3. In some embodiments, epitaxial sub-region 108B4 can act as a capping layer to prevent out-diffusion of dopants from epitaxial sub-regions 108B1, 108B2, and 108B3 and to protect S/D region 108 during subsequent processing of PFET 102P.

In some embodiments, epitaxial sub-regions 108B1, 108B2, 108B3, and 108B4 can include epitaxially-grown SiGe layers and can differ from each other based on a relative concentration of Ge atoms with respect to Si atoms. In some embodiments, epitaxial sub-region 108B1 can include a Ge atom concentration of about 15 atomic % to about 20 atomic % with any remaining atomic % being Si atoms and can have thickness of about 3 nm to about 4 nm. In some embodiments, each of epitaxial sub-regions 108B2, 108B3, and 108B4 can include a Ge atom concentration of about 45 atomic % to about 55 atomic % with any remaining atomic % being Si atoms.

In some embodiments, epitaxial sub-regions 108B1, 108B2, 108B3, and 108B4 can differ from each other based on p-type dopant (e.g., boron atoms or gallium atoms) concentrations. In some embodiments, epitaxial sub-region 108B1 can include a boron dopant concentration of about 7×10²⁰ atoms/cm³ to about 8×10²⁰ atoms/cm³. In some embodiments, epitaxial sub-region 108B2 can include a boron dopant concentration of about 8×10²⁰ atoms/cm³ to about 1×10²¹ atoms/cm³. In some embodiments, each of epitaxial sub-regions 108B3 and 108B4 can include a boron dopant concentration of about 1×10²¹ atoms/cm³ to about 2×10²¹ atoms/cm³.

Referring to FIGS. 1A and 1O, in some embodiments, NFET 102N can include (i) a fin base 107 (also referred to as a “sheet base 107”) disposed on substrate 104, (ii) S/D regions 109 disposed on fin base 107, (iii) nanostructured channel regions 110 disposed adjacent to S/D regions 109, (iv) gate structures 112 surrounding nanostructured channel regions 110, (v) conductive capping layers 114, (vi) insulating capping layers 116, (vii) outer gate spacers 118 disposed along sidewalls of gate structures 112, (viii) inner gate spacers 120 disposed along sidewalls of S/D regions 109, (ix) ESLs 122 disposed directly on S/D regions 109, (x) ILD layers 124 disposed directly on ESLs 122, and (xi) isolation structures 126 disposed under S/D regions 109. S/D regions 109 may refer to a source or a drain, individually or collectively dependent upon the context. The discussion of elements in FIGS. 1A-1O with the same annotations applies to each other, unless mentioned otherwise.

In some embodiments, fin base 107 can include n-type dopants (e.g., phosphorus or arsenic). In some embodiments, for NFET 102N, the WFM layer of gate structures 112 can include titanium aluminum (TiAl), titanium aluminum carbide (TiAlC), tantalum aluminum (TaAl), tantalum aluminum carbide (TaAlC), Al-doped Ti, Al-doped TiN, Al-doped Ta, Al-doped TaN, or other suitable Al-based materials.

In some embodiments, each S/D region 109 can include (i) S/D sub-regions 109A epitaxially grown on sidewalls of nanostructured channel regions 110, (ii) a S/D sub-region 109B epitaxially grown on S/D sub-regions 109A, (iii) a S/D sub-regions 109C epitaxially grown on S/D sub-regions 109B, (iv) a S/D sub-region 109D epitaxially grown on S/D sub-regions 109C, and (v) S/D sub-region 109E epitaxially grown on S/D sub-regions 109D. S/D sub-regions 109A can be disposed directly on and can be. In some embodiments, the number of S/D sub-regions 109A in each S/D region 109 can be equal to the number of nanostructured channel regions 110 facing each S/D region 109. For example, as shown in FIG. 1O, S/D region 109 includes eight S/D sub-regions 109A, which is equal to the eight nanostructured channel regions 110 facing S/D region 109.

In some embodiments, S/D sub-regions 109A, 109B, 109C, 109D, and 109E can include epitaxially-grown Si layers without any Ge atoms and can differ from each other based on n-type dopant (e.g., phosphorus or arsenic atoms) concentrations. In some embodiments, S/D sub-regions 109A can be undoped. In some embodiments, S/D sub-regions 109B can include an arsenic dopant concentration of about 1×10²⁰ atoms/cm³ to about 1×10²¹ atoms/cm³. In some embodiments, S/D sub-regions 109C can include a phosphorus dopant concentration of about 1×10²¹ atoms/cm³ to about 4×10²¹ atoms/cm³. In some embodiments, each of S/D sub-regions 109D and 109E can include a phosphorus dopant concentration of about 1×10²¹ atoms/cm³ to about 2×10²¹ atoms/cm³.

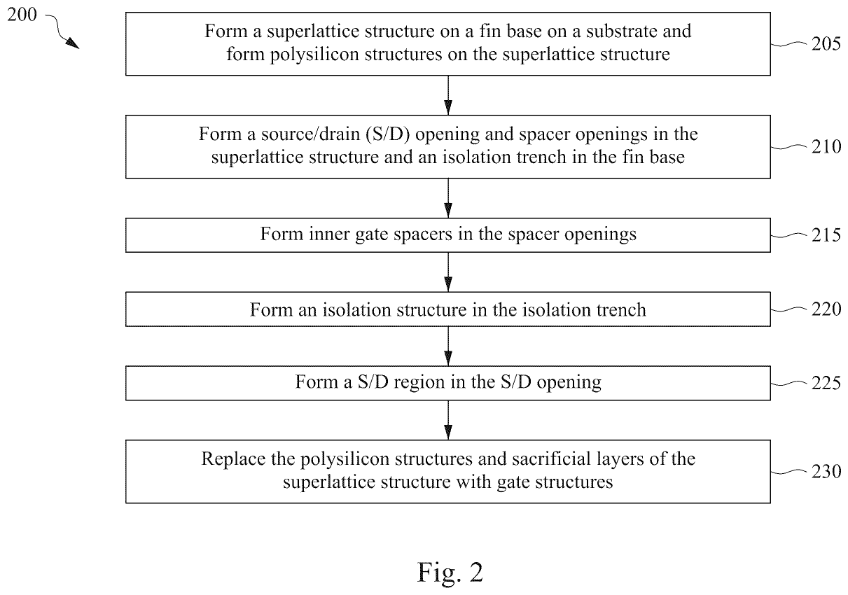

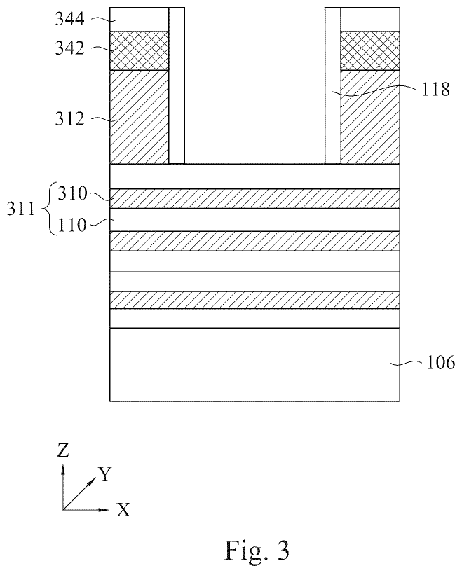

FIG. 2 is a flow diagram of an example method 200 for fabricating PFET 102P as described above with reference to FIGS. 1A-1H, according to some embodiments. For illustrative purposes, the operations illustrated in FIG. 2 will be described with reference to the example fabrication process for fabricating PFET 102P as illustrated in FIGS. 3-9. FIGS. 3-9 are cross-sectional views of PFET 102P along line A-A of FIG. 1A at various stages of fabrication, according to some embodiments. Operations can be performed in a different order or not performed depending on specific applications. It should be noted that method 200 may not produce a complete PFET 102P. Accordingly, it is understood that additional processes can be provided before, during, and after method 200, and that some other processes may only be briefly described herein. The discussion of elements in FIGS. 1A-1H and 3-9 with the same annotations applies to each other, unless mentioned otherwise.

Referring to FIG. 2, in operation 205, a superlattice structure is formed on a fin base, and polysilicon structures are formed on the superlattice structure. For example, as described with reference to FIG. 3, a superlattice structure 311 (also referred to as “nanosheet stack 311”) is formed on fin base 106, and polysilicon structures 312 are formed on superlattice structure 311. In some embodiments, hard mask layers 342 and 344 can be formed during the formation of polysilicon structures 312. Superlattice structure 311 can include nanostructured layers 110 and 310 arranged in an alternating configuration. In some embodiments, nanostructured layers 110 can include Si and nanostructured layers 310 can include SiGe. In some embodiments, each of nanostructured layers 110 and 310 can have a thickness of about 3 nm to about 15 nm along a Z-axis. Nanostructured layers 310 are also referred to as “sacrificial layers 310.” During subsequent processing, polysilicon structures 312 and sacrificial layers 310 can be replaced with gate structures 112 in a gate replacement process.

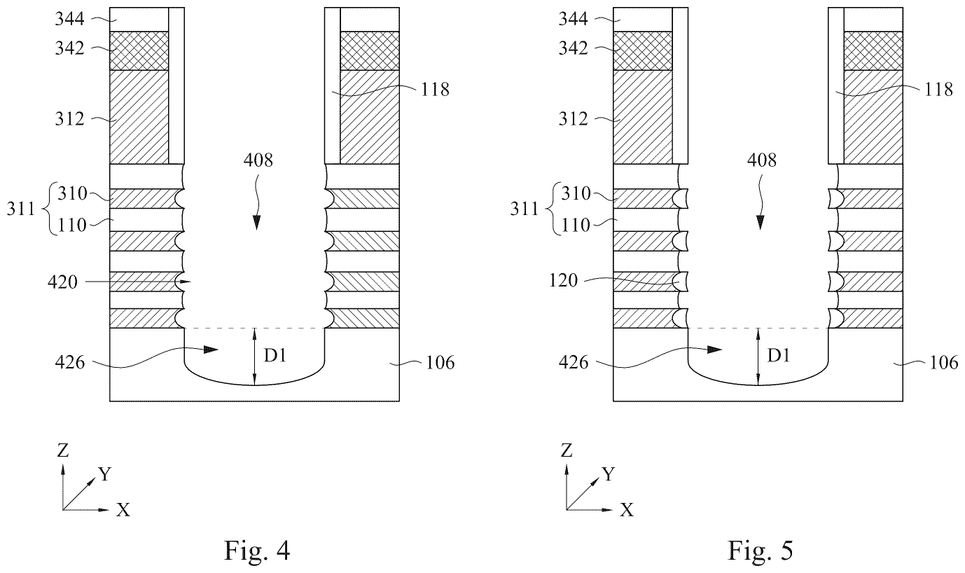

Referring to FIG. 2, in operation 210, a S/D opening and spacer openings are formed in the superlattice structure and an isolation trench is formed in the fin base. For example, as described with reference to FIG. 4, a S/D opening 408 and spacer openings 420 are formed in superlattice structure 311 and an isolation trench 426 is formed in fin base 106. S/D opening 408 can be formed by etching the portions of superlattice structure 311 not covered by polysilicon structures 312. The formation of S/D opening 408 can be followed by the formation of isolation trench 426 extending distance D1 into fin base 106. In some embodiments, isolation trench 426 can be formed by performing an etching process on a portion of fin base 106 exposed in S/D opening 408.

In some embodiments, the etching of superlattice structure 311 and fin base 106 can include a plasma-based dry etching process using etching gases, such as carbon tetrafluoride (CF₄), sulfur dioxide (SO₂), hexafluoroethane (C₂F₆), chlorine (Cl₂), nitrogen trifluoride (NF₃), sulfur hexafluoride (SF₆), and hydrogen bromide (HBr), with mixture gases, such as hydrogen (H₂), oxygen (O₂), nitrogen (N₂), and argon (Ar). The etching can be performed at a temperature ranging from about 25° C. to about 200° C. under a pressure from about 5 mTorr to about 50 mTorr. The flow rate of the etching gases can range from about 5 standard cubic centimeters per minute (sccm) to about 100 sccm. The plasma power can range from about 50 W to about 200 W with a bias voltage from about 30 V to about 200 V.

The formation of isolation trench 426 can be followed by the formation of spacer openings 420 by performing an etching process on sidewalls of sacrificial layers 310 facing S/D openings 408. The etching process can laterally etch sacrificial layers 310 to laterally recess the sidewalls of sacrificial layers 310 with respect to sidewalls of nanostructured layers 110 facing S/D openings 408. The etching process can include a dry etching process that has a higher etch selectivity for SiGe of sacrificial layers 310 than Si of nanostructured layers 110. For example, halogen-based chemistries can exhibit etch selectivity that is higher for Ge than for Si. Therefore, halogen gases can etch SiGe faster than Si. In some embodiments, the halogen-based chemistries can include fluorine-based and/or chlorine-based gasses. Alternatively, the etching of sacrificial layers 310 can include a wet etching process with a higher selectivity for SiGe than Si. For example, the wet etching process can include using a mixture of sulfuric acid (H₂SO₄) and hydrogen peroxide (H₂O₂) and/or a mixture of ammonia hydroxide (NH₄OH) with H₂O₂ and deionized (DI) water.

Referring to FIG. 2, in operation 215, inner gate spacers are formed in the spacer openings. For example, as described with reference to FIG. 5, inner gate spacers 120 are formed in spacer openings 420. The formation of inner gate spacers 120 can include sequential operations of (i) depositing a dielectric material layer (not shown) on the structure of FIG. 4, and (ii) etching the dielectric material layer to form the structure of FIG. 5. In some embodiments, the etching of the dielectric material layer can be an anisotropic dry etching process and can have a higher etching rate along a Z-axis rather than along an X-axis or a Y-axis. As a result, the portions of the dielectric material layer in S/D openings 408 and isolation trench 426 can be etched without etching the portions of the dielectric material layer in spacer openings 420.

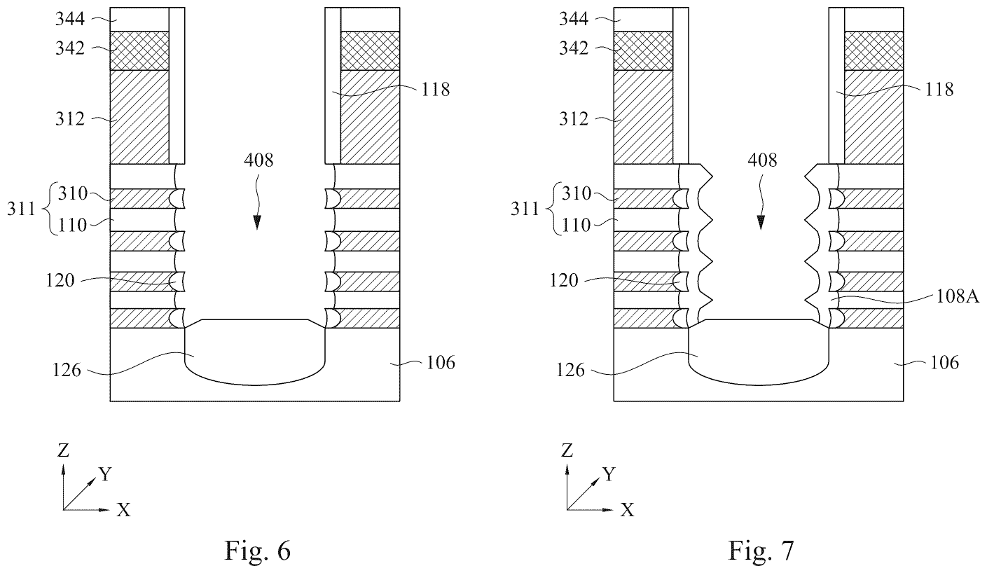

Referring to FIG. 2, in operation 220, an isolation structure is formed in the isolation trench. For example, as described with reference to FIG. 6, isolation structure 126 is formed in isolation trench 426. In some embodiments, the formation of isolation structure 126 can include epitaxially growing an undoped silicon layer on the exposed surfaces of fin base 106 in isolation trench 426.

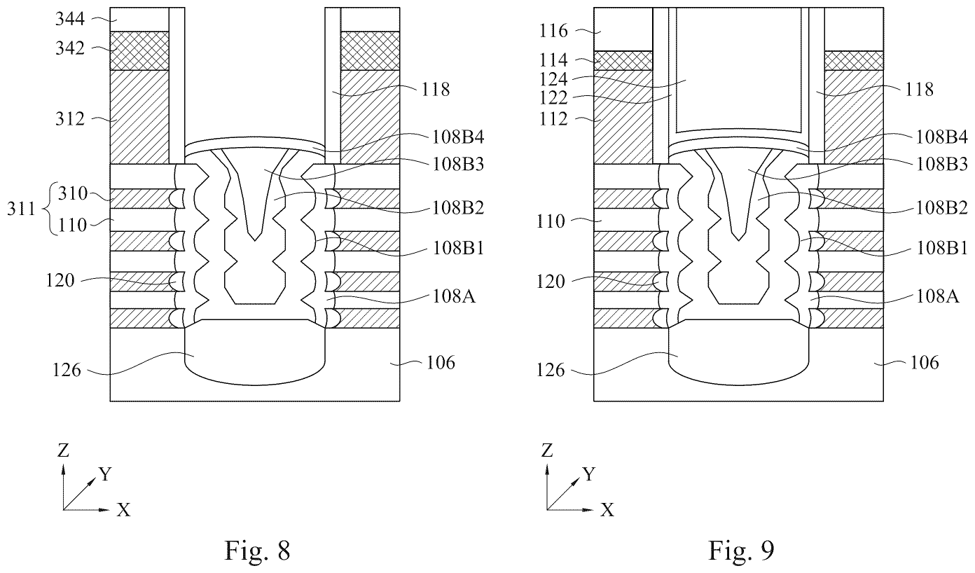

Referring to FIG. 2, in operation 225, a S/D region is formed in the S/D opening. For example, as described with reference to FIGS. 7 and 8, S/D region 108 is formed in S/D opening 408. The formation of S/D region 108 can include sequential operations of (i) epitaxially growing epitaxial liners 108A on the sidewalls of nanostructured layers 110 facing S/D opening 408, as shown in FIG. 7, (ii) epitaxially growing epitaxial sub-region 108B1 on epitaxial liners 108A, as shown in FIG. 8, (iii) epitaxially growing epitaxial sub-region 108B2 on epitaxial sub-region 108B1, as shown in FIG. 8, (iv) epitaxially growing epitaxial sub-region 108B3 on epitaxial sub-region 108B3, and (v) epitaxially growing epitaxial sub-region 108B4 on epitaxial sub-regions 108B1, 108B2, and 108B3, as shown in FIG. 8. In some embodiments, the epitaxial growth of epitaxial liners 108A can start by growing epitaxial layers directly on the sidewalls of nanostructured layers 110. The epitaxial growth of epitaxial liners 108A can be continued until the epitaxial layers vertically extend to merge with each other and form a continuous layer on the sidewalls of nanostructured layers 110 and inner gate spacers 120, as shown in FIG. 7.

In some embodiments, epitaxially growing epitaxial liners 108A can include exposing S/D opening 408 to a Si precursor gas (e.g., dichlorosilane (DCS) gas or silane (SiH₄) gas) and a boron precursor gas (e.g., diboron (B₂H₆) gas) at a temperature of about 500° C. to about 700° C. and a pressure of about 20 torr to about 80 torr. In some embodiments, epitaxial liners 108A having the stack of two layers—outer liner 130A and inner liner 130B—as described above with reference to FIG. 1D can be formed in a dual temperature epitaxial process. In some embodiments, outer liner 130A can be formed at a lower temperature than inner liner 130B. In some embodiments, S/D opening 408 can be exposed to the Si precursor gas at a temperature of about 400° C. to about 500° C. and a pressure of about 20 torr to about 30 torr to grow the undoped Si layer of outer liner 130A. Following the growth of outer liner 130A, S/D opening 408 and outer liner 130A can be exposed to the Si precursor gas and the boron precursor gas at a temperature of about 500° C. to about 700° C. and a pressure of about 20 torr to about 80 torr to grow the doped Si layer of inner liner 130B.

In some embodiments, during the epitaxial growth of epitaxial liners 108A, S/D opening 408 can also be exposed to an etching gas, such as a hydrogen chloride (HCl) gas with a gas flow rate of about 1 sccm to about 200 sccm to control the thickness of epitaxial liners 108A. In some embodiments, S/D opening 408 can be exposed to the etching gas with a gas flow rate of about 50 sccm when S/D opening 408 is exposed to the boron precursor gas with a gas flow rate of about 100 sccm.

Within the above discussed ranges of temperature, pressure, and gas flow rates, epitaxial liners 108A can be epitaxially grown with an adequate thickness and dopant concentration for functioning as an ESL and for reducing or minimizing parasitic resistances and capacitances and DIBL effects in PFET 102P.

In some embodiments, the formation of S/D region 108 can be followed by the formation of ESLs 122 and ILD layers 124, as shown in FIG. 9.

Referring to FIG. 2, in operation 230, the polysilicon structures and sacrificial layers of the superlattice structure are replaced with gate structures. For example, as described with reference to FIG. 9, polysilicon structures 312 and sacrificial layers 310 are replaced with gate structures 112. The formation of gate structures 112 can include removing hard mask layers 342 and 344, polysilicon structures 312, and sacrificial layers 310 from the structure of FIG. 8 to form gate openings (not shown), and forming gate structures 112 in the gate openings, as shown in FIG. 9. In some embodiments, the formation of gate structures 112 can be followed by the formation of conductive capping layers 114 and insulating capping layers 116, as shown in FIG. 9.

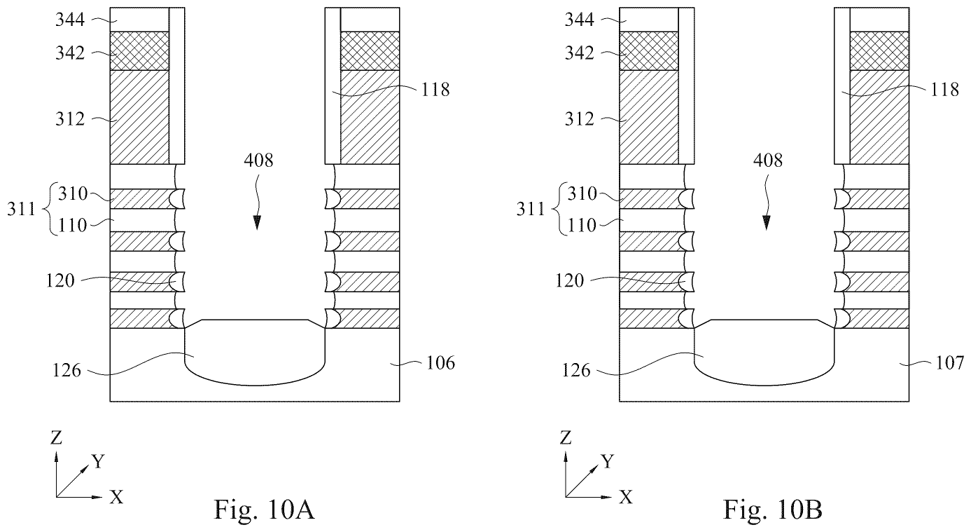

In some embodiments, method 200 of FIG. 2 can be used to form PFET 102P and NFET 102N substantially parallel to each other on same substrate 104. In some embodiments, the elements of PFET 102P and NFET 102N can be formed at the same time, except for their S/D regions, which can be formed sequentially. FIGS. 10A-13A and 10B-13B illustrate the sequential formation of S/D regions 108 of PFET 102P and S/D regions 109 of NFET 102N. FIGS. 10A-13A show cross-sectional views of PFET 102P along line A-A of FIG. 1A and FIGS. 10B-13B show cross-sectional views of NFET 102N along line D-D of FIG. 1A at various stages of their fabrication, according to some embodiments. The discussion of elements in FIGS. 1A-1O, 10A-13A, and 10B-13B with the same annotations applies to each other, unless mentioned otherwise.

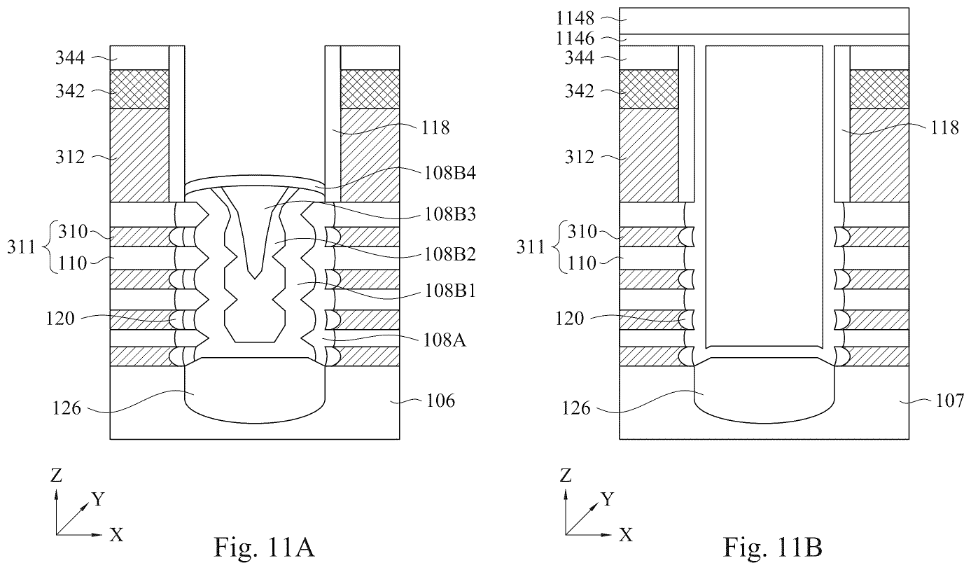

Prior to the formation of S/D regions 108 and 109, the structures of FIGS. 10A and 10B can be formed by performing operations 205, 210, 215, and 220 of FIG. 2 on substrate 104. Fin bases 106 and 107 can be substantially parallel to each other. In some embodiments, the formation of S/D regions 109 can be followed by the formation of S/D regions 108. The formation of S/D regions 108 can include sequential operations of (i) depositing a bottom anti-reflective coating (BARC) layer 1146 on the structure of NFET 102N in FIG. 10B to form the structure of FIG. 11B, (ii) depositing a hard mask layer 1148 (e.g., aluminum oxide (AlOₓ) layer) on BARC layer 1146, (iii) performing operation 225 of FIG. 2 on the structure of PFET 102P in FIG. 10A to form S/D region 108, as shown in FIG. 11A, and (iv) removing hard mask layer 1148 and BARC layer 1146 from the structure of FIG. 11B. BARC layer 1146 and hard mask layer 1148 can prevent S/D regions 108 from being formed in S/D opening 408 of NFET 102N.

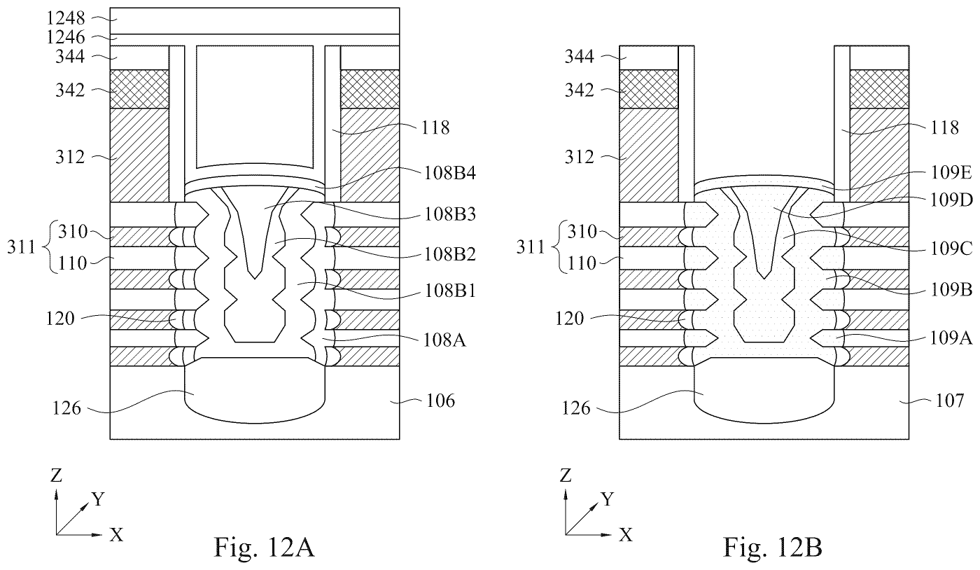

Similar to the formation of S/D regions 108, the formation of S/D regions 109 can include sequential operations of (i) depositing a BARC layer 1246 on the structure of PFET 102P in FIG. 11A to form the structure of FIG. 12A, (ii) depositing a hard mask layer 1248 (e.g., AlOₓ layer) on BARC layer 1246, (iii) performing operation 225 of FIG. 2 on the structure of NFET 102N after removing hard mask layer 1148 and BARC layer 1146 to form S/D region 109, as shown in FIG. 12B, and (iv) removing hard mask layer 1248 and BARC layer 1246 from the structure of FIG. 12A. BARC layer 1246 and hard mask layer 1248 can prevent S/D region 109 from being formed on S/D region 108.

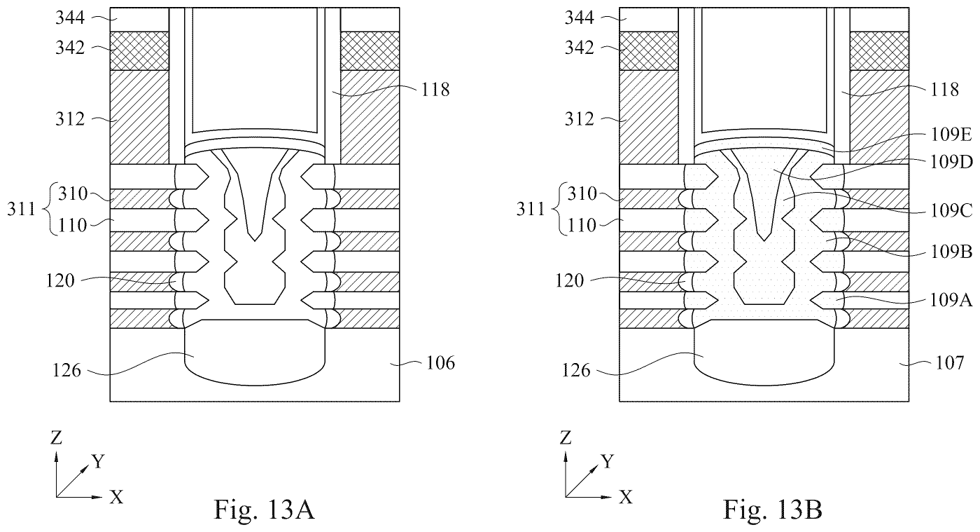

In some embodiments, the formation of S/D regions 108 and 109 can be followed by the formation of ESLs 122 and ILD layers 124, as shown in FIGS. 13A and 13B. In some embodiments, operation 230 can be performed on the structures of FIGS. 13A and 13B to form gate structures 112 in PFET 102P and NFET 102N.

The present disclosure provides examples methods of forming epitaxial p-type S/D regions (e.g., S/D region 108) on nanostructured channel regions (e.g., nanostructured channel regions 110) to improve the epitaxial growth quality of the p-type S/D regions and reduce parasitic resistances and capacitances and DIBL effects in the GAA FETs. In some embodiments, a p-type S/D region can include a Ge-based epitaxial region (e.g., Ge-based epitaxial region 108B) and epitaxial liners (e.g., epitaxial liners 108A) along sidewalls of the Ge-based epitaxial region. The epitaxial liners can be formed as a continuous layer on sidewalls of the nanostructured channel regions and inner spacers (e.g., inner spacers 120) facing the Ge-based epitaxial region of the p-type S/D region. And, the Ge-based epitaxial region can be epitaxially grown on the epitaxial liners. The epitaxial growth of the Ge-based epitaxial region on the continuous layer of the epitaxial liners can improve the epitaxial growth quality of the Ge-based epitaxial region by preventing or minimizing the formation of defects in the Ge-based epitaxial region, thus improving the S/D performance. The epitaxial liners can also prevent the Ge-based epitaxial region from being in contact with the inner spacers, thus reducing parasitic resistances and capacitances and DIBL effects in the GAA FETs.

In some embodiments, the Ge-based epitaxial region can include a silicon-germanium (SiGe) region with a Ge concentration of about 15 atomic % to about 50 atomic %. In some embodiments, the epitaxial liners can include an undoped silicon (Si) layer or a doped Si layer. In some embodiments, the doped Si layer can include boron and/or gallium dopants. In some embodiments, the concentration of boron and/or gallium dopants can be about 1×10²⁰ atoms/cm³ to about 5×10²¹ atoms/cm³. In some embodiments, the epitaxial liners can be Ge-free or can have a low concentration of Ge atoms (e.g., about 1 atomic % to about 20 atomic %, or about 6 atomic % to about 12 atomic %). In some embodiments, the portions (e.g., portions 108A1) of the epitaxial liners on the sidewalls of the nanostructured channel regions can be thicker than the portions (e.g., portions 108A2) of the epitaxial liners on the sidewalls of the inner spacers. In some embodiments, the epitaxial liners can have a thickness of about 1 nm to about 12 nm for adequately forming a continuous layer on the sidewalls of the nanostructured channel regions and inner spacers facing the Ge-based epitaxial region.

In some embodiments, a semiconductor device includes a substrate, first and second nanostructured channel regions disposed on the substrate, a gate structure surrounding the first and second nanostructured channel regions, an inner gate spacer disposed along a sidewall of the gate structure and between the first and second nanostructured channel regions, and a S/D region. The S/D region includes an epitaxial liner disposed along sidewalls of the first and second nanostructured channel regions and the inner gate spacer and a germanium-based epitaxial region disposed on the epitaxial liner. The semiconductor further includes an isolation structure disposed between the germanium-based epitaxial region and the substrate.

In some embodiments, a semiconductor device includes a substrate, first and second nanosheet layers disposed on the substrate, first and second gate structures surrounding the first and second nanosheet layers, respectively, first and second gate spacers disposed along sidewalls of the first and second gate structures, respectively, and a S/D region. The S/D region includes a first germanium-free epitaxial liner disposed as a continuous layer along sidewalls of the first nanosheet layer and the first gate spacer, a second germanium-free epitaxial liner disposed as a continuous layer along sidewalls of the second nanosheet layer and the second gate spacer, and a germanium-based epitaxial region disposed between the first and second germanium-free epitaxial liners.

In some embodiments, a method includes forming a nanosheet stack having nanostructured layers and sacrificial layers on a substrate, forming a polysilicon structure on the nanosheet stack, etching the nanostructured layers and sacrificial layers to form a S/D opening and an isolation trench in the nanosheet stack, forming inner spacers on sidewalls of the sacrificial layers, forming an undoped semiconductor layer in the isolation trench, forming a germanium-free epitaxial liner as a continuous layer on sidewalls of the nanostructured layers and the inner spacers, and epitaxially growing a germanium-based layer on the germanium-free epitaxial liner and the undoped semiconductor layer.

The foregoing disclosure outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
first and second nanostructured channel regions disposed on the substrate;
a gate structure surrounding the first and second nanostructured channel regions;
a gate spacer disposed along a sidewall of the gate structure and between the first and second nanostructured channel regions; and
a source/drain (S/D) region, comprising:
a germanium-free liner disposed along sidewalls of the first and second nanostructured channel regions and along a sidewall of the gate spacer; and
a germanium-based region disposed along a sidewall of the germanium-free liner.

2. The semiconductor device of claim 1, wherein the germanium-free liner comprises a width greater than widths of the first and second nanostructured channel regions.

3. The semiconductor device of claim 1, wherein the germanium-free liner extends laterally over top and bottom surfaces of the gate spacer.

4. The semiconductor device of claim 1, wherein the germanium-free liner comprises:
a first portion with a first thickness disposed on the sidewalls of the first and second nanostructured channel regions; and
a second portion with a second thickness disposed on the sidewall of the gate spacer, wherein the first thickness is greater than the second thickness.

5. The semiconductor device of claim 1, wherein the germanium-free liner comprises:
a first sidewall with a faceted cross-sectional profile; and
a second sidewall with a curved cross-sectional profile.

6. The semiconductor device of claim 1, wherein the germanium-free liner comprises an undoped silicon layer.

7. The semiconductor device of claim 1, wherein the germanium-free liner comprises a silicon layer having boron or gallium dopants.

8. The semiconductor device of claim 1, wherein the germanium-free liner comprises:
an undoped silicon layer disposed on the sidewalls of the first and second nanostructured channel regions and the gate spacer; and
a doped silicon layer disposed on the undoped silicon layer.

9. The semiconductor device of claim 1, wherein the germanium-free liner comprises:
a first doped silicon layer with a first concentration of dopants disposed on the sidewalls of the first and second nanostructured channel regions and the gate spacer;
an undoped silicon layer disposed on the first doped silicon layer; and
a second doped silicon layer with a second concentration of dopants disposed on the undoped silicon layer, wherein the second concentration is greater than the first concentration.

10. The semiconductor device of claim 1, wherein the germanium-based region extends laterally over a top surface of the germanium-free liner.

11. A semiconductor device, comprising:
a substrate;
a first stack of nanostructured channel regions disposed on the substrate;
a second stack of nanostructured channel regions disposed on the substrate;
first and second gate structures surrounding the first and second stack of nanostructured channel regions, respectively;
first and second gate spacers disposed along sidewalls of the first and second gate structures, respectively; and
a source/drain (S/D) region, comprising:
a first liner disposed along sidewalls of the first stack of nanostructured channel regions and the first gate spacer;
a second liner disposed along sidewalls of the second stack of nanostructured channel regions and the second gate spacer; and
a germanium-based region disposed between the first and second liners.

12. The semiconductor device of claim 11, wherein the germanium-based region extends laterally over top surfaces of the first and second liners.

13. The semiconductor device of claim 11, wherein the first and second liners comprise germanium-free liners.

14. The semiconductor device of claim 11, further comprising an undoped semiconductor layer disposed between the first and second stack of nanostructured channel regions, wherein bottom surfaces of the first and second liners and the germanium-based region are in contact with a top surface of the undoped semiconductor layer.

15. The semiconductor device of claim 11, wherein the first and second liners comprise undoped silicon layers.

16. The semiconductor device of claim 11, wherein sidewalls of the first and second liners facing each other comprise faceted cross-sectional profiles.

17. A method, comprising:
forming, on a substrate, a nanosheet stack comprising nanostructured layers and sacrificial layers;
forming a polysilicon structure on the nanosheet stack;
etching the nanostructured layers and sacrificial layers to form an opening in the nanosheet stack;
forming inner spacers on sidewalls of the sacrificial layers in the opening;
epitaxially growing a germanium-free liner on sidewalls of the nanostructured layers; and
epitaxially growing a germanium-based layer on the germanium-free liner.

18. The method of claim 17, wherein epitaxially growing the germanium-free liner comprises epitaxially growing undoped silicon layers on the sidewalls of the nanostructured layers.

19. The method of claim 17, wherein epitaxially growing the germanium-free liner comprises epitaxially growing boron-doped or gallium-doped silicon layers on the sidewalls of the nanostructured layers.

20. The method of claim 17, wherein epitaxially growing the germanium-free liner comprises:
epitaxially growing an undoped silicon layer on the sidewalls of the nanostructured layers; and
epitaxially growing a doped silicon layer on the undoped silicon layer.
